(19) United States
(12) Patent Application Publication
(10) Pub. No.: US 2010/0117209 A1
(43) Pub. Date: May 13, 2010

(54) MULTIPLE CHIPS ON A SEMICONDUCTOR CHIP WITH COOLING MEANS

(76) Inventors: Raschid J. Bezama, Mahopac, NY (US); Minhua Lu, Mohegan Lake, NY (US); Lawrence S. Mok, Brewster, NY (US)

Correspondence Address: HOFFMAN WARNICK LLC, 75 State Street, 14th Floor, ALBANY, NY, 12207, US

(21) Appl. No.: 11/680,311

(22) Filed: Feb. 28, 2007

(51) Int. Cl. H01L 23/52; H01L 23/46

(52) U.S. Cl. 257/686; 257/714; 257/E23.141; 257/E23.097

(57) ABSTRACT

The present invention is directed to a method of packaging multiple semiconductor chips on a second semiconductor chips with a built-in efficient cooling means. One embodiment is to place two multiple chip stacks on opposing sides of a vapor chamber for transferring heat away from the semiconductor chips. Another embodiment is to construct a vapor chamber with a substrate such that at least one multiple chip stack is embedded inside the vapor chamber.

### BACKGROUND OF THE INVENTION

1. Field of the Invention

The invention is in the field of semiconductor chip packaging. Specifically, the invention provides a solution that improves the packaging density and cooling capability of multiple densely packed semiconductor chips.

2. Related Art

This invention is to solve the packaging and heat dissipation problem of a group of semiconductor chips soldered tightly together, for instance, a group of memory chips soldered on a memory controller chip. In this case, heat generated within each of the memory chips and the controller chip must be removed in order to maintain the temperatures in these chips in the desired operating temperature. Furthermore, it is required to maintain the temperature difference among those chips within a reasonable range.

Heretofore, various solutions have been proposed to remove or reduce heat generation. Unfortunately, none of the existing solutions provide the results needed for optimal performance. In view of the foregoing, there exists a need for an approach.

### SUMMARY OF THE INVENTION

The invention is to integrate a silicon vapor chamber with at least one multiple chip stack, in which the multiple chip stack(s) are mounted (e.g., soldered) on a semiconductor chip or a substrate. One embodiment is to place a vapor chamber close to (e.g., in between) the multiple chip stack(s), and another embodiment is to place the multiple chip stack(s) within a vapor chamber formed with the packaging substrate. The multiple chip stack(s) can be mounted on the chip either vertically or in an angle. Another embodiment uses flexible, thin circuit means to connect the chips together.

A first aspect of the present invention provides a multiple chip package, comprising: a first multiple chip stack; a second multiple chip stack; a semiconductor chip on which the first multiple chip stack and the second multiple chip stack are mounted; and a vapor chamber interposed between the first multiple chip stack and the second multiple chip stack.

A second aspect of the present invention provides a multiple chip package, comprising: a first multiple chip stack; a second multiple chip stack; a semiconductor chip on which the first multiple chip stack and the second multiple chip stack are mounted; and a set of pulsating heat pipes interposed between the first multiple chip stack and the second multiple chip stack.

A third aspect of the present invention provides a multiple chip package, comprising: a semiconductor chip mounted on a substrate; at least one multiple chip stack mounted on the semiconductor chip; and a vapor chamber mounted on the substrate, the semiconductor chip and the multiple chip package being disposed inside of the vapor chamber.

### BRIEF DESCRIPTION OF THE DRAWINGS

These and other features of this invention will be more readily understood from the following detailed description of the various aspects of the invention taken in conjunction with the accompanying drawings in which:

FIG. 1 shows is a perspective view of a the semiconductor chip package having multiple chips soldered on a chip and a T-shaped vapor chamber according to the present invention.

FIG. 2 shows an arrangement of multiple chips soldered on a semiconductor chip according to the present invention.

FIG. 3 shows a cross-sectional view of the T-shaped vapor chamber according to the present invention.

FIG. 4 shows a cross-sectional view of the T-shape chamber using alternative pulsating heat pipes according to the present invention.

FIG. 5 shows a detailed structure of multiple chips inside a vapor chamber according to the present invention.

FIG. 6 shows another embodiment of multiple chips inside a vapor chamber according to the present invention.

FIG. 7 shows another arrangement of the wicks and chips inside a vapor chamber according to the present invention.

FIG. 8 shows another embodiment of multiple chips inside a vapor chamber according to the present invention.

FIG. 9 shows another embodiment of multiple chips inside a vapor chamber according to the present invention.

FIG. 10 shows an illustration of the cross-section view of the capillary channels formed with C4 process according to the present invention.

FIG. 11 shows a top view of the FIG. 10 according to the present invention.

The drawings are not necessarily to scale. The drawings are merely schematic representations, not intended to portray specific parameters of the invention. The drawings are intended to depict only typical embodiments of the invention, and therefore should not be considered as limiting the scope of the invention. In the drawings, like numbering represents like elements.

### DETAILED DESCRIPTION OF THE INVENTION

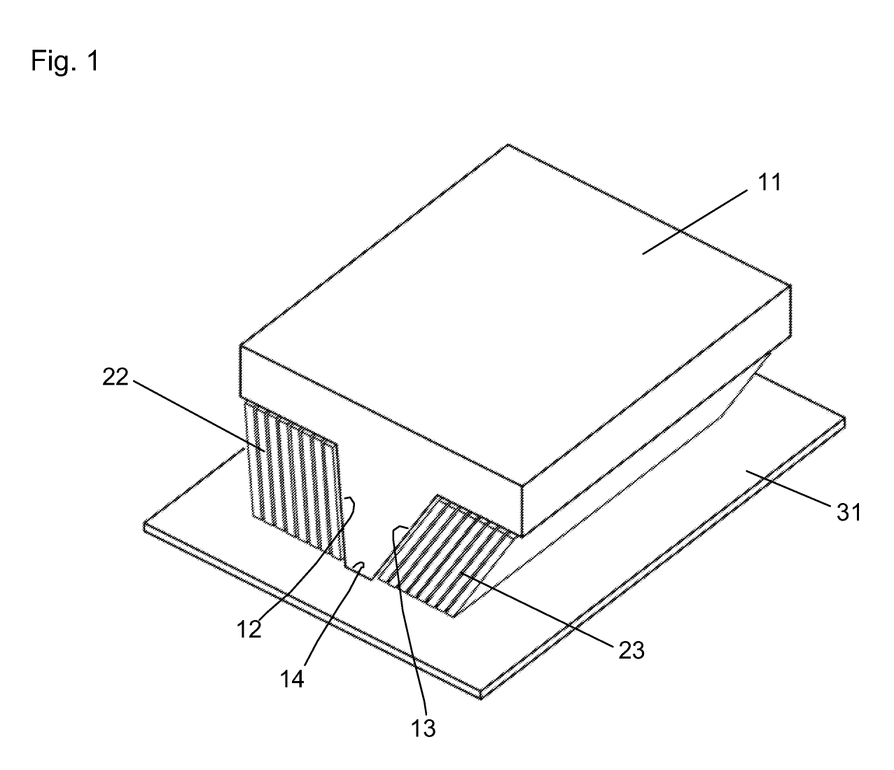

FIG. 1 shows the perspective view of an exemplified multiple chip packaging with a T-shaped vapor chamber for efficient heat transfer. As illustrated in the Fig., the T-shaped vapor chamber 11 are placed between two multiple chip stacks 22 and 23. The two side walls 12 and 13 on the T-shaped vapor chamber 11 are in good thermal contact with the two multiple chip stacks 22 and 23. There are optional thermal interface materials, which are not shown in the FIG. 1, between the side walls 12 and 13, and the outer surface of the multiple chips stacks 22 and 23, respectively. The bottom side of the T-shaped vapor chamber 11 is also in good thermal contact with the chip 31 underneath. The chip 31 could be an active chip that provides communication hub or control to the multiple chip stacks, or a passive chip for connection among the chips. The chip 31 is then mounted on a substrate which is not shown in the Fig. and provides the necessary electrical power to the multiple chip stacks 22 and 23 and signal paths to the other circuitry in a system.

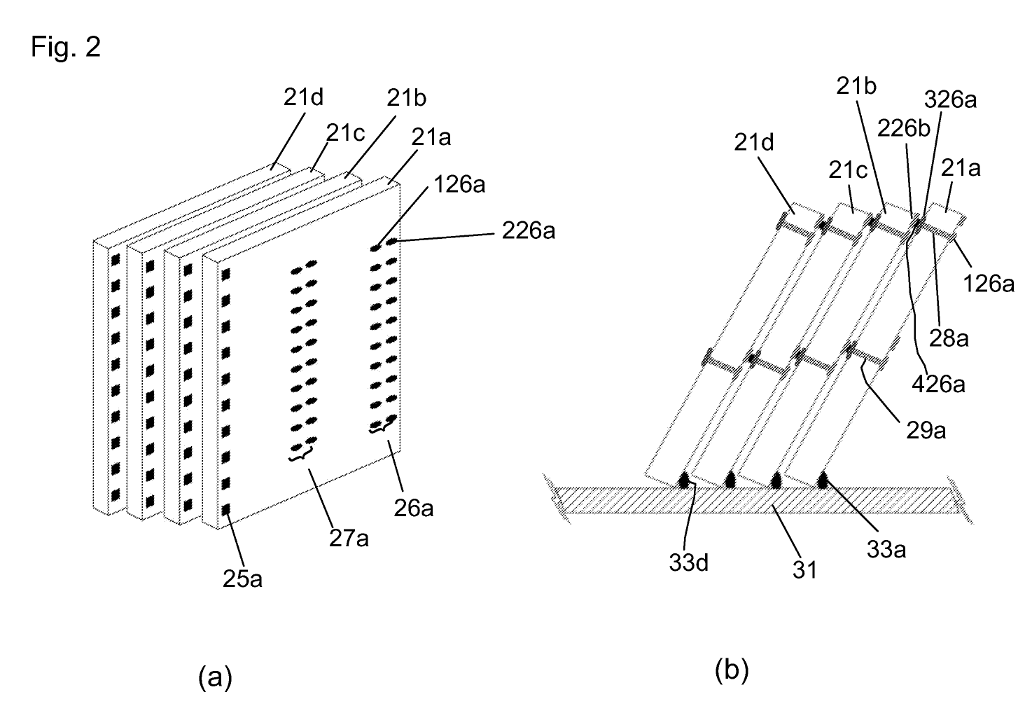

FIGS. 2a and 2b show the detailed structure of the multiple chip stacks 22 and 23 depicted in FIG. 1. For the clarification of illustration, only four chips are shown in the FIG. 1. In practice, there is no limit on the number of chips in the multiple chip stacks, provided that the thermal performance of the assembly is within prescribed limits. In the chip stack, each semiconductor chip 21a to 21d can have different types of connection pads, such as pads 25, 26, and 27, on the chip. The connection pads 25a to 25d are placed near one edge of the chips 21a to 21d, respectively. Those connection pads 25a to 25d are used mainly to connect to a substrate 31 for power, ground, and electrical signals. The connection pads 25a to 25d can be identical or different among the chips in one chip stack depending on the signaling requirement. The connection pads 26a and 27a on the chip 21a are for connection to other chips through the in-chip vias 28a and 29a. The connection pads 26a have two sub-pads 126a and 226a on the side that has active devices of the chip 21a. The two sub-pads 126a and 226a are connected together electrically. The sub-pad 126a is then connected through a via 28a to a sub-pad 326a on the back side of the chip 21a. The sub-pad 326a is then soldered to the sub-pad 226b on the front side of the adjacent chip 21b through the solder ball 426a. Similar arrangement is also applied to the rest of the sub-pads in the connection pads 26a as well as the sub-pads in the connection pads 27a. This connection arrangement of pads gives a means to connect the chips 21a to 21d directly and hence shortens the length of signal paths among chips. It also makes possible to mount the multiple chip stack in an angle to the substrate 31 by the solder balls 33a to 33d. After assembly, the gaps between adjacent chips 21a to 21d can be filled with an epoxy to minimize the chip stack thermal resistance.

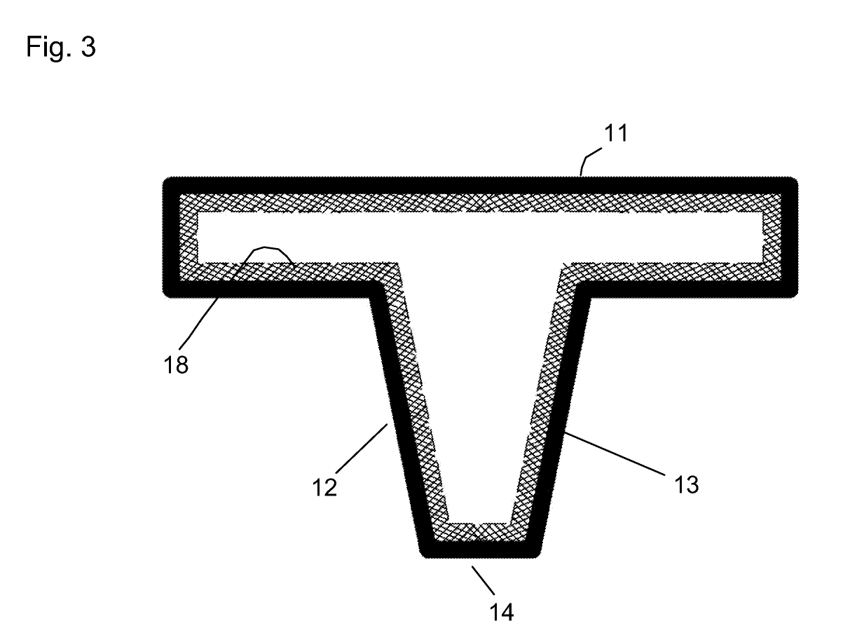

FIG. 3 is a cross-sectional view of the exemplified T-shaped vapor chamber 11. While this particular cross-section shape is preferred, other shapes are also possible, for example by including multiple portions comprising walls 12, 13, and 14, but preserving the given geometric shape of these three walls. Walls 12, 14, and 13 make the evaporator section of the vapor chamber, and the shape shown provides variable area for the vapor phase to travel to the condenser side (top wall). Vapor chamber 11 is a vacuum tight hollow chamber filled partially with fluids such as water, ethanol, ammonia, butane, etc, or mixtures thereof. The walls of vapor chamber 11 are made of materials such as silicon, silicon carbide, silicon alloys, copper, copper alloys, etc. There are wicks 18 adhered on the inner surface of the vapor chamber 11. The wicks 18 are made from fibers, meshes, etc. Alternatively, the wicks 18 could be grooves etched on the inner surface of the chamber walls.

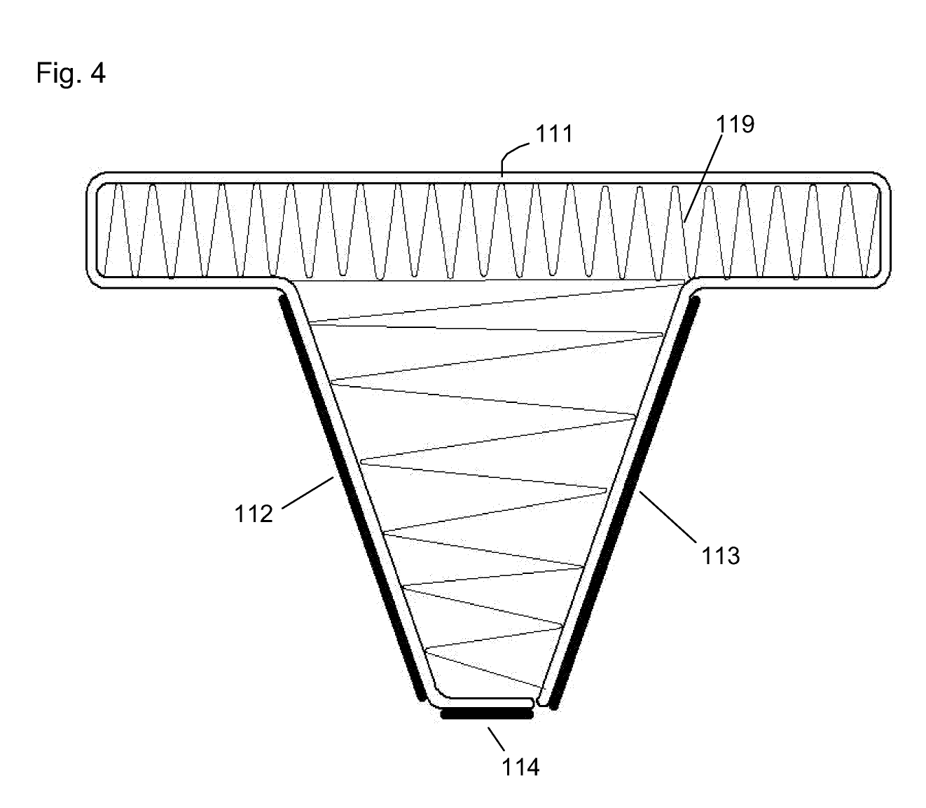

FIG. 4 shows another method of extracting heat from the multiple chip stacks 22 and 23 (not shown) by using a bunch of thin pulsating heat pipes 111 to form a similar shape as the vapor chamber 11 shown in FIG. 3. In this arrangement, the thin pulsating heat pipes 111 are folded around heat sinks fins 119. The pieces designated 112, 113, and 114 are thermally conductive plates made of copper or aluminum to be put in contact with the multiple chip stacks 22 and 23 shown in FIG. 1. Heat generated in the chip stacks 22 and 23 will conduct to the pieces 112, 113, and 114 of the pulsating heat pipes 111 and distribute to the heat sink fins 119 by them. Air moving among the heat sink fins 119 will then carry the heat away.

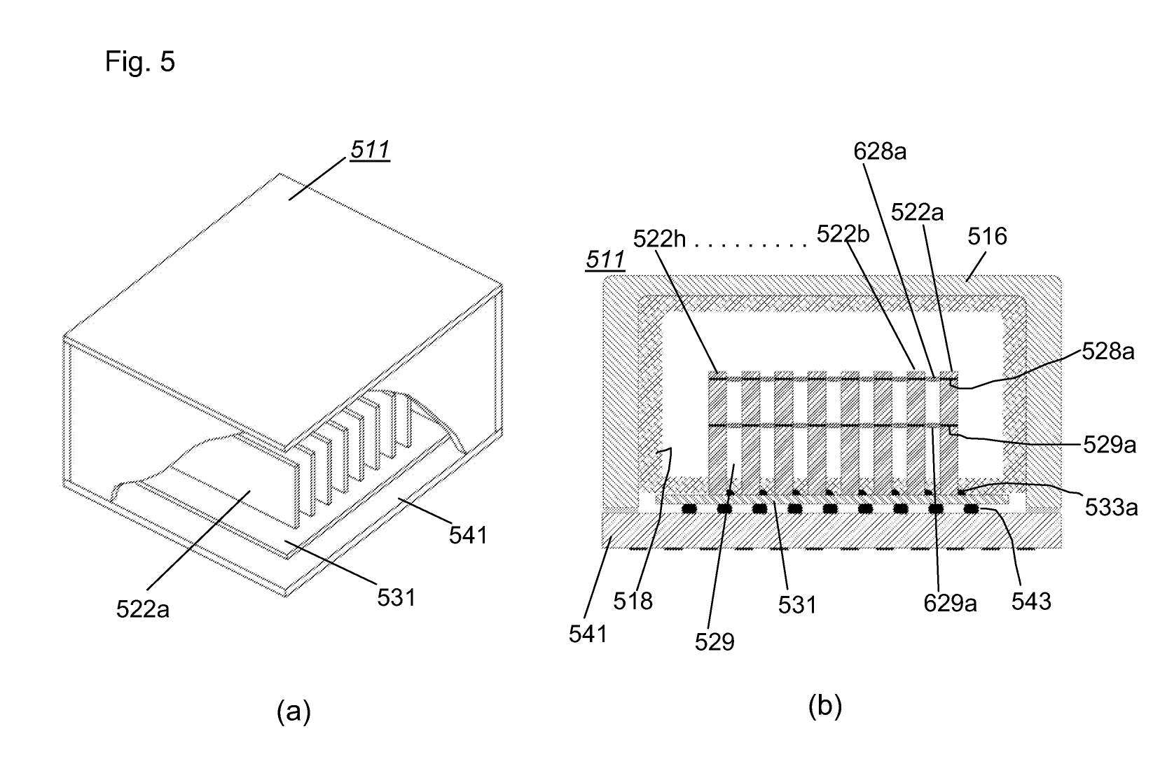

FIGS. 5(a-b) is an exemplified embodiment of the multiple chip package inside a vapor chamber. FIG. 5(a) shows a cut-away view of a vapor chamber 511 showing the arrangement of the multiple chips 522a soldered on a chip 531 and FIG. 5(b) shows the cross-sectional view of the vapor chamber 511. As shown in FIG. 5(b), eight chips 522a to 522h are soldered on a chip 531 vertically by numerous solder balls 533a, which, in turn, soldered on a substrate 541 using another set of solder balls 543. The vapor chamber 511 is formed by soldering the chamber cover 516 to the substrate 541 and the vapor chamber 511 is evacuated and partially filled with non-reacting working fluids such as ethanol, butane, etc., or mixtures thereof. For the clarification of this illustration, the fill ports are not shown in FIGS. 5(a-b) and the number of chips is also not necessary restricted to eight as shown in FIG. 5(a-b). The wicks 518 are placed on the inner surface of the vapor chamber cover 516 and the back side of the chip 531. The eight chips 522a to 522h have additional connection paths provided by the solder columns 628a and 629a. Each chip has in-chip vias 528a and 529a to allow signals to travel from the front to the back side of the chip. For the clarification of illustration, the necessary metal layers on the connection pads are not shown in the Fig. The spacing 529 between chips is also used as the channel to guide the fluids moving upward from the wicks 518. This upward moving fluids will be heated up by the chips and vaporize along the way to provide cooling to the chips.

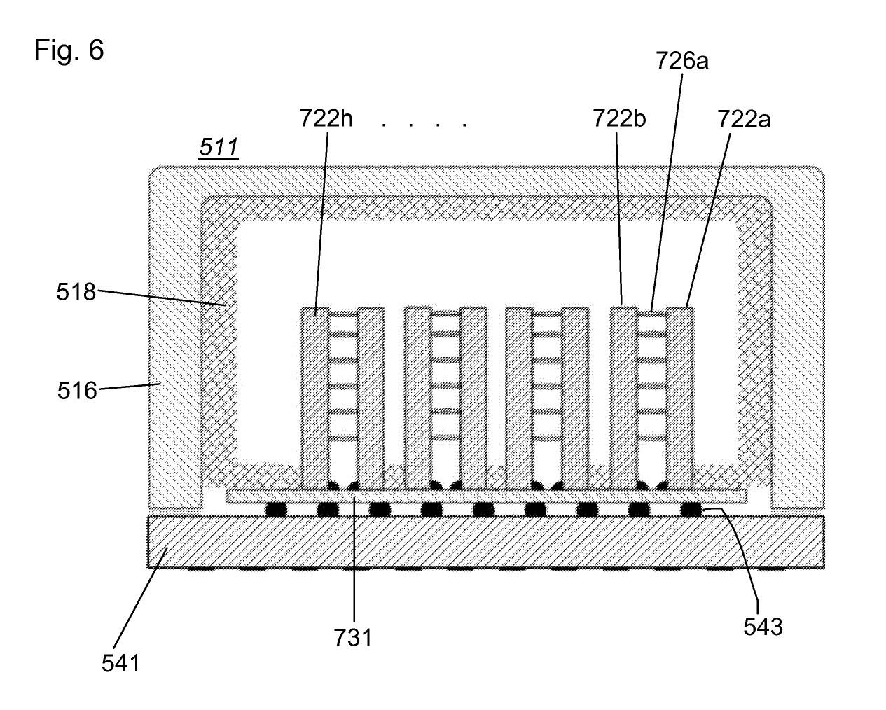

FIG. 6 shows another arrangement of multiple chips in the vapor chamber 511. In this arrangement, a pair of chips, for example chip 722a and chip 722b are soldered together with their front surfaces facing each other using the solder columns 726a. This arrangement is suitable to those semiconductor chips that do not have in-chip vias to bring signals from the front to the back surface.

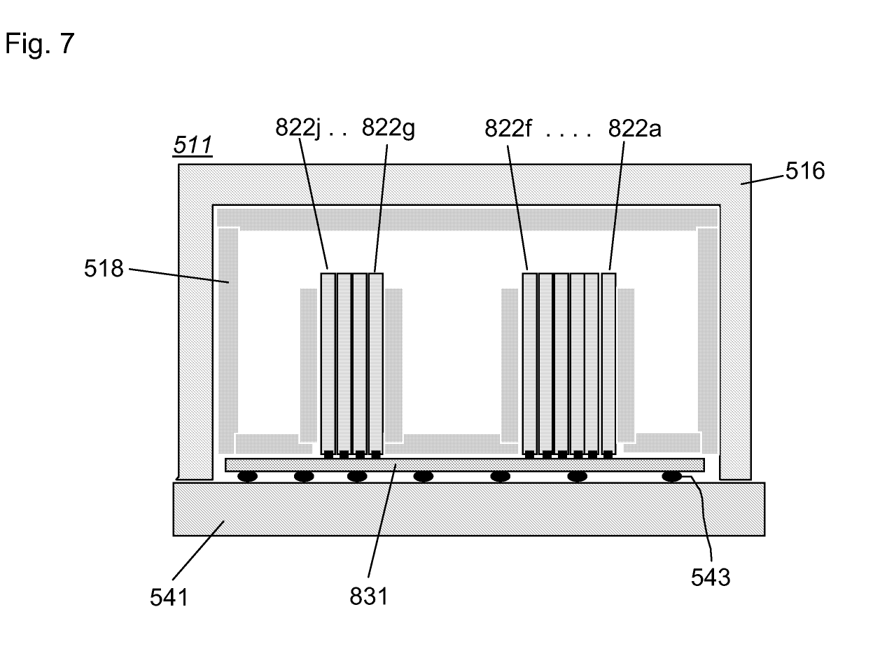

FIG. 7 shows another arrangement of multiple chips in the vapor chamber 511. In this arrangement, the chips 822a to 822j are soldered directly on a chip and no additional inter-chip connections are needed.

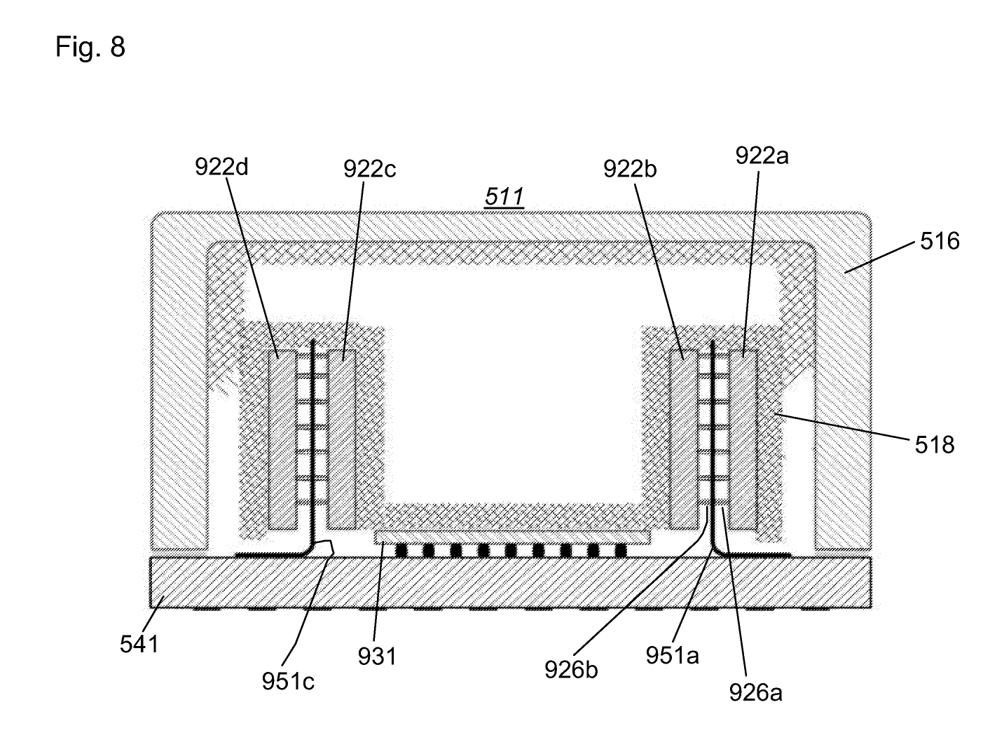

FIG. 8 is another arrangement of multiple chips in the vapor chamber 511. In this arrangement, flexible circuit 951a is used to connect electrical signals between the chips 922a and 922b, and the substrate 541. The two chips 922a and 922b are soldered on both sides of the flexible circuit 951a using soldered balls 926a and 926b and likewise for chips 922c and 922d. The wicks 518 inside the chamber are placed on the inner surface of the chamber as well as the back surfaces of the chips. The signal paths among the chips 922a to 922d and chip 931 are all through the substrate 541.

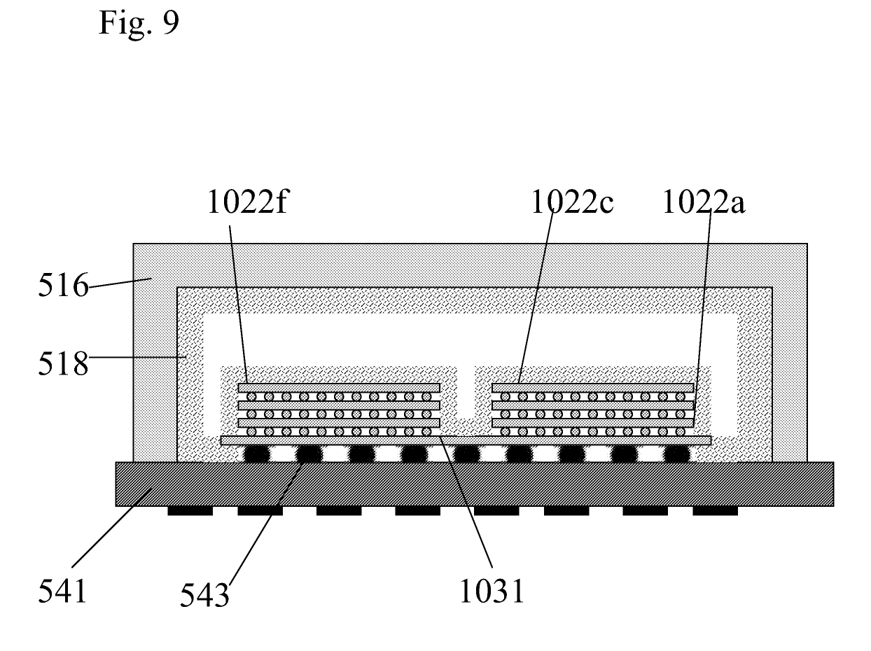

FIG. 9 is another arrangement of multiple chips in the vapor chamber 511. In this arrangement, the chips 1022a to 1022f are soldered through micro C4s on a high density chip carrier 1031 such as silicon carrier and then connected to substrates 541 through C4s 543. Each chip 1022a-10022f can be a single chip or a stacked chips connected either from edge or by vias. The wicks 518 inside the chamber are placed on the inner surface of the chamber as well as the back surfaces of the chips. The signal paths among the chips 1022a to 1022f and chip carrier 1031 are all through the substrate 541. Alternatively, the chips can be stacked staggered from each other in the manner shown in FIG. 2a, and then wire-bonded to the carrier 1031 if micro C4's are not feasible.

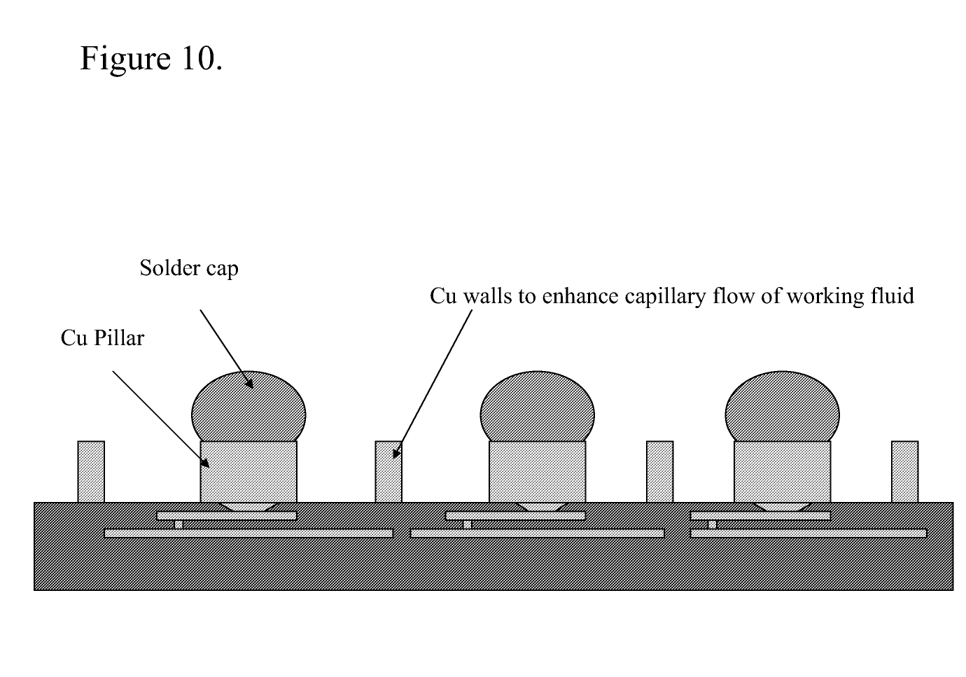

FIG. 10 is an illustration of the cross-section view of the capillary channels formed with C4 process. The chip could be one of the 1022a-1022f in FIG. 9, where no under fill is used since the bonding is between silicon and silicon. The channels formed with C4 process will help to drive the working fluid through the gap of the chip stack, so that the stacked chips could be cooled more effectively from inside of the stack.

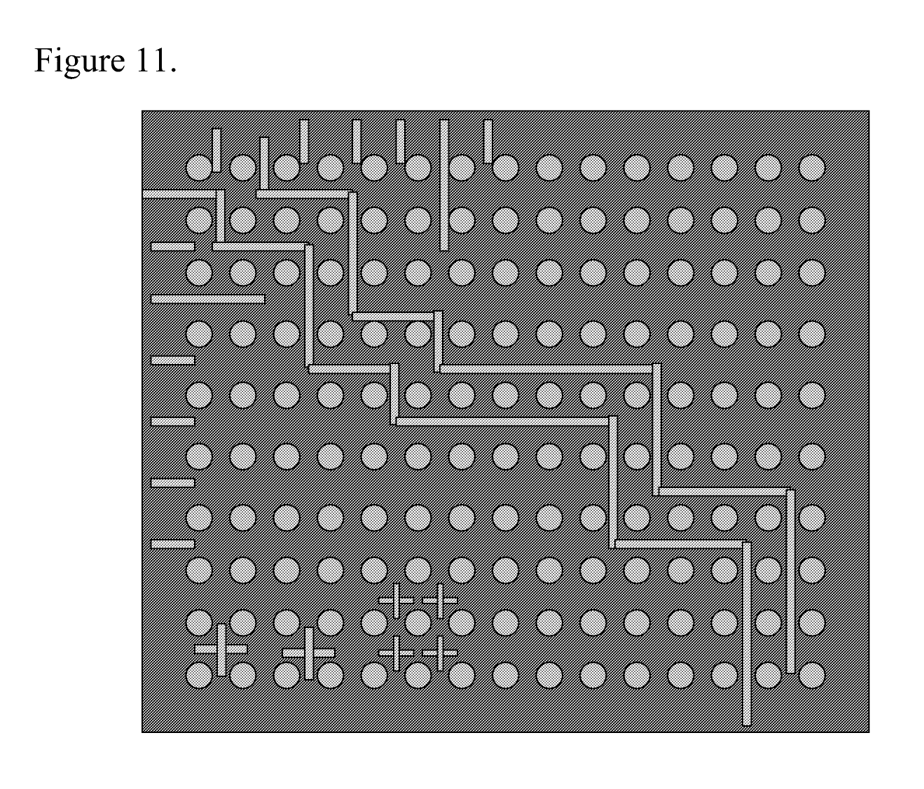

FIG. 11 is a top view of the FIG. 10. In FIG. 11, only one channel is illustrated. The channel should be designed to guild to fluid to flow from edge of the chip to center or hot spot of the chip. The shape and the pitch of the chip would take C4 density and layout and position of the hot spot into consideration. One variation of the channel is simple cross inserted in between each or every a few of the C4s.

We claim:

1. A multiple chip package, comprising:
a first multiple chip stack;
a second multiple chip stack;
a semiconductor chip on which the first multiple chip stack and the second multiple chip stack are mounted; and
a vapor chamber interposed between the first multiple chip stack and the second multiple chip stack.

2. The multiple chip package of claim 1, the vapor chamber having a first side in electrical contact with the first multiple chip stack, a second side in electrical contact with the second multiple chip stack, and a third side in electrical contact with the semiconductor chip.

3. The multiple chip package of claim 1, the first multiple chip stack and the second multiple chip stack being mounted at an angle on the semiconductor chip.

4. The multiple chip package of claim 1, the first multiple chip stack and the second multiple chip stack being mounted vertically on the semiconductor chip.

5. The multiple chip package of claim 1, the first multiple chip stack and the second multiple chip stack being mounted at an angle on the semiconductor chip.

6. The multiple chip package of claim 1, the first multiple chip stack and the second multiple chip stack both comprises a plurality of chips that are interconnected using connection pads.

7. The multiple chip package of claim 1, the vapor chamber being T-Shaped.

8. The multiple chip package of claim 1, the vapor chamber comprising a vacuum tight hollow chamber partially filled with at least one fluid, and having a set of walls from a material selected from a group consisting of silicon, silicon carbide, silicon alloys, copper, and copper alloys.

9. The multiple chip package of claim 8, the vapor chamber further comprising a set of wicks adhered on an inner surface of the vapor chamber.

10. The multiple chip package of claim 9, the wicks being formed from a material selected from a group consisting of fiber, and mesh.

11. The multiple chip package of claim 9, the wicks comprising grooves etched on an inner surface of the vapor chamber.

12. A multiple chip package, comprising:
a first multiple chip stack;
a second multiple chip stack;
a semiconductor chip on which the first multiple chip stack and the second multiple chip stack are mounted; and
a set of pulsating heat pipes interposed between the first multiple chip stack and the second multiple chip stack.

13. The multiple chip package of claim 12, the set of pulsating heat pipes being folded around a set of heat sinks.

14. The multiple chip package of claim 13, further comprising a set of thermally conductive plates interposed between the set of pulsating heat pipes and the first chip package and the second chip package.

15. A multiple chip package, comprising:
a semiconductor chip mounted on a substrate;
at least one multiple chip stack mounted on the semiconductor chip; and
a vapor chamber mounted on the substrate, the semiconductor chip and the multiple chip package being disposed inside of the vapor chamber.

16. The multiple chip package of claim 15, the vapor chamber being evacuated and partially filled with at least one non-reactive fluid.

17. The multiple chip package of claim 16, the at least one non-reactive fluid being selected from a group consisting of ethanol, butane and mixtures thereof.

18. The multiple chip package of claim 15, further comprising a set of wicks disposed along inner surfaces of the vapor chamber and along a top surface of the semiconductor chip.
